(19) United States
(12) Patent Application Publication
(10) Pub. No.: US 2025/0324842 A1
(43) Pub. Date: Oct. 16, 2025

(54) DISPLAY DEVICE AND METHOD OF MANUFACTURING THE SAME

(71) Applicant: Samsung Display Co., LTD., Yongin-si (KR)

(72) Inventor: Chun Gi YOU, Yongin-si (KR)

(21) Appl. No.: 19/019,062

(22) Filed: Jan. 13, 2025

(30) Foreign Application Priority Data
Apr. 11, 2024 (KR) 10-2024-0048636

(51) Int. Cl. H10H 29/856; H10H 29/01; H10H 29/24; H10H 29/80; H10K 59/12; H10K 59/80; H10K 102/00

(52) U.S. Cl. CPC H10H 29/856; H10H 29/012; H10H 29/24; H10H 29/8325; H10K 59/1201; H10K 59/8051; H10K 2102/311

(57) ABSTRACT

A display device includes: an anode including an exposure area and a contact area; a mirror layer overlapping with the anode; and a via located between the anode and the mirror layer. The mirror layer includes: a first barrier layer; a reflective electrode on the first barrier layer; and a second barrier layer on a portion of the reflective electrode.

### CROSS-REFERENCE TO RELATED APPLICATION

The present application claims priority to and the benefit of Korean Patent Application No. 10-2024-0048636, filed on Apr. 11, 2024, in the Korean Intellectual Property, the entire disclosure of which is incorporated by reference herein.

### BACKGROUND

### 1. Field

Aspects of some embodiments of the present disclosure relate to a display device, and a method of manufacturing the display device.

### 2. Description of the Related Art

With the development of information technologies, the importance of a display device, which is a connection medium between a user and information, has increased. Accordingly, various display devices, such as a liquid crystal display device and an organic light emitting display device, are increasingly being used.

The above information disclosed in this Background section is for enhancement of understanding of the background of the present disclosure, and therefore, it may contain information that does not constitute prior art.

### SUMMARY

Some embodiments of the present disclosure may be directed to a display device capable of preventing or substantially preventing damage of an anode, and a method of manufacturing the display device.

According to one or more embodiments of the present disclosure, a display device includes: an anode including an exposure area and a contact area; a mirror layer overlapping with the anode; and a via located between the anode and the mirror layer. The mirror layer includes: a first barrier layer; a reflective electrode on the first barrier layer; and a second barrier layer on a portion of the reflective electrode.

In some embodiments, the second barrier layer may overlap with the contact area.

In some embodiments, one end of the via may be in contact with the second barrier layer, and another end of the via may be in contact with the contact area.

In some embodiments, the second barrier layer may include titanium nitride.

In some embodiments, the second barrier layer may not overlap with the exposure area.

In some embodiments, the reflective electrode may include aluminum.

In some embodiments, the first barrier layer may include at least one of titanium or titanium nitride.

In some embodiments, the via may include: a protective layer on the second barrier layer, and having a concave portion; and a filler filling the concave portion.

In some embodiments, the protective layer may include: a first protective layer on the second barrier layer, the first protective layer having a first concave portion; and a second protective layer on the first concave portion, the second protective layer having a second concave portion.

In some embodiments, the filler may include tungsten.

According to one or more embodiments of the present disclosure, a method of manufacturing a display device, includes: forming a second barrier layer on a portion of a reflective electrode, the reflective electrode being disposed on a first barrier layer; forming a via layer covering the reflective electrode and the second barrier layer; forming a via penetrating the via layer on the second barrier layer, and generating a polymer layer; and removing the polymer layer.

In some embodiments, the second barrier layer may be formed at a position overlapping with a contact area of an anode.

In some embodiments, the second barrier layer may not be formed at a position overlapping with an exposure area of the anode.

In some embodiments, the second barrier layer may include titanium nitride.

In some embodiments, the forming of the via may include: forming a via hole by removing a portion of the via layer on the second barrier layer; filling the via hole with a protective layer having a concave portion; and filling the concave portion with a filler.

In some embodiments, the via layer may be removed through a chemical mechanical polishing process.

In some embodiments, the filling of the via hole with the protective layer may include: filling the via hole with a first protective layer having a first concave portion; and filling the first concave portion with a second protective layer having a second concave portion.

In some embodiments, the filler may include tungsten.

In some embodiments, the polymer layer may be removed by a cleaning agent.

In some embodiments, the cleaning agent may include hydrogen fluoride.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram of a display device according to some embodiments.

FIG. 2 is a block diagram of a sub-pixel according to some embodiments.

FIG. 3 is a plan view of a display panel according to some embodiments.

FIG. 4 is a sectional view of a display panel according to some embodiments.

FIG. 5 is a plan view of a pixel according to some embodiments.

FIG. 6 is a sectional view taken along the line I-I′ of FIG. 5 according to some embodiments.

FIG. 7 is a sectional view of a light emitting structure according to some embodiments.

FIG. 8 is a sectional view of a light emitting structure according to some embodiments.

FIG. 9 is an enlarged view of the area A of FIG. 6.

FIGS. 10-15 are sectional views of a method of manufacturing a display device according to some embodiments.

FIG. 16 is a block diagram of a display system according to some embodiments.

FIGS. 17-20 are perspective views of some application examples of the display system of FIG. 16.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

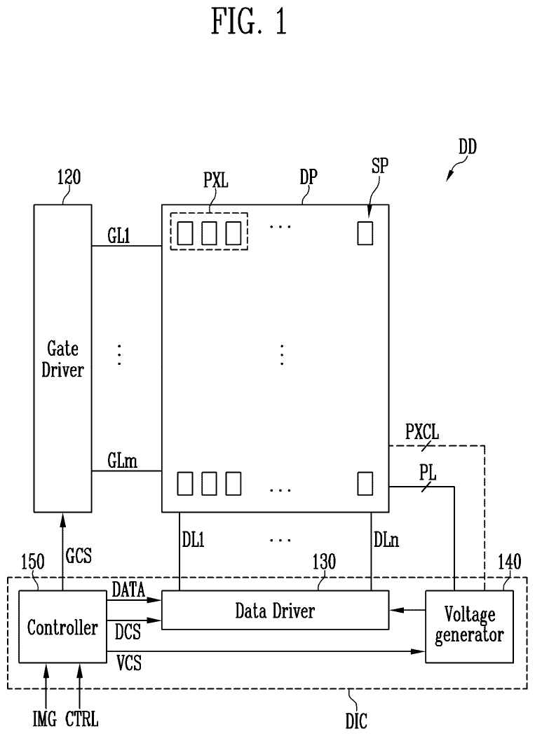

FIG. 1 is a block diagram of a display device according to some embodiments.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to mth gate lines GL1 to GLm, where m is a natural number. The sub-pixels SP may be connected to the data driver 130 through first to nth data lines DL1 to DLn, where n is a natural number.

The sub-pixels SP may generate light of two or more colors. For example, each of the sub-pixels SP may generate light of red, green, blue, cyan, magenta, yellow, white, and/or the like.

Two or more sub-pixels from among the sub-pixels SP may constitute a pixel PXL. For example, the pixel PXL may include three sub-pixels SP as shown in FIG. 1. As such, the pixel PXL may emit light of various colors with various luminances according to a combination of the light emitted from the sub-pixels SP included therein.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In one or more embodiments, the gate control signal GCS may include a start signal indicating a start of each frame, a horizontal synchronization signal, and the like.

The gate driver 120 may be disposed at one side of the display panel DP. However, the present disclosure is not limited thereto. For example, the gate driver 120 may be divided into two or more drivers that are physically and/or logically divided from each other, and these drivers may be disposed at one side of the display panel DP and another side (e.g., an opposite side) of the display panel DP, which is opposite to the one side. As such, in some embodiments, the gate driver 120 may be disposed in various suitable forms at the periphery of the display panel DP.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In one or more embodiments, the data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. When a gate signal is applied to each of the first to mth gate lines GL1 to GLm, data signals corresponding to the image data DATA may be applied to the first to nth data lines DL1 to DLm. Accordingly, corresponding sub-pixels SP may generate light corresponding to the data signals. As such, an image may be displayed on the display panel DP.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages, and may provide the generated voltages to the components of the display device DD. The voltage generator 140 may generate the plurality of voltages by receiving an input voltage from the outside of the display device DD, and regulating the received input voltage.

The voltage generator 140 may generate a first power voltage and a second power voltage. The generated first and second power voltages may be provided to the sub-pixels SP through power lines PL. In other embodiments, at least one of the first and/or second power voltages may be provided from the outside of the display device DD.

In some embodiments, the voltage generator 140 may provide various desired voltages and/or signals. For example, the voltage generator 140 may provide one or more initialization voltages applied to the sub-pixels SP. As an example, in a sensing operation for sensing electrical characteristics of transistors and/or light emitting elements of the sub-pixels SP, a reference voltage (e.g., a predetermined reference voltage) may be applied to the first to nth data lines DL1 to DLn, and the voltage generator 140 may generate the reference voltage to transfer the reference voltage to the data driver 130. For example, in a display operation for displaying an image on the display panel DP, common pixel control signals may be applied to the sub-pixels SP, and the voltage generator 140 may generate the pixel control signals. In some embodiments, the voltage generator 140 may provide the pixel control signals to the sub-pixels SP through pixel control lines PXCL. FIG. 1 illustrates that the pixel control lines PXCL are connected between the voltage generator 140 and the display panel DP. However, the present disclosure is not limited thereto. For example, the pixel control lines PXCL may be connected between the gate driver 120 and the display panel DP. In this case, the pixel control signals may be transferred to the pixel control lines PXCL from the voltage generator 140 through the gate driver 120.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In one or more embodiments, the controller 150 may align the input image data IMG to be suitable for the sub-pixels SP in units of rows, thereby outputting the image data DATA.

Two or more components from among the data driver 130, the voltage generator 140, and/or the controller 150 may be mounted together on one integrated circuit. As shown in FIG. 1, the data driver 130, the voltage generator 140, and the controller 150 may be included in a driver integrated circuit DIC. The data driver 130, the voltage generator 140, and the controller 150 may be components that are functionally divided in one driver integrated circuit DIC. In other embodiments, at least one of the data driver 130, the voltage generator 140, and/or the controller 150 may be provided as a component distinguished from (e.g., that is separate from or different from) the driver integrated circuit DIC.

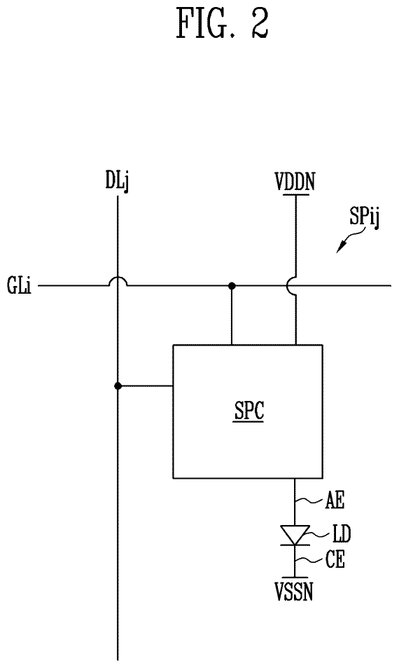

FIG. 2 is a block diagram of a sub-pixel according to some embodiments. In FIG. 2, the sub-pixel SPij arranged on an ith row (where i is an integer greater than or equal to 1 and smaller than or equal to m) and a jth column (where j is an integer greater than or equal to 1 and smaller than or equal to n) from among the sub-pixels SP described above with reference to FIG. 1 is illustrated as a representative example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN is connected to one of the power lines PL described above with reference to FIG. 1 to receive a first power voltage. The second power voltage node VSSN is connected to another one of the power lines PL to receive a second power voltage. The first power voltage may have a voltage level higher than a voltage level of the second power voltage.

The light emitting element LD may be connected between (or may include) an anode AE and a cathode CE. The anode AE may be connected to the first power voltage node VDDN through the sub-pixel circuit SPC. For example, the anode AE may be connected to the first power voltage node VDDN through one or more transistors included in the sub-pixel circuit SPC. The cathode CE may be connected to the second power voltage node VSSN. The light emitting element LD may emit light according to a current flowing from the anode AE to the cathode CE.

The sub-pixel circuit SPC may be connected to an ith gate line GLi from among the first to mth gate lines GL1 to GLm described above with reference to FIG. 1, and a jth data line DLj from among the first to nth data lines DL1 to DLn described above with reference to FIG. 1. In response to a gate signal received through the ith gate line GLi, the sub-pixel circuit SPC controls the light emitting element LD to emit light according to a data signal received through the jth data line DLj. In some embodiments, the sub-pixel circuit SPC may be further connected to the pixel control lines PXCL shown in FIG. 1. The sub-pixel circuit SPC may control the light emitting element LD in further response to control signals received through the pixel control lines PXCL.

Accordingly, the sub-pixel circuit SPC may include circuit elements, for example, such as a plurality of transistors and one or more capacitors.

The transistors of the sub-pixel circuit SPC may include P-type transistors and/or N-type transistors. In some embodiments, the transistors of the sub-pixel circuit SPC may include a Metal Oxide Silicon Field Effect Transistor (MOSFET). In some embodiments, the transistors of the sub-pixel circuit SPC may include an amorphous silicon semiconductor, a monocrystalline silicon semiconductor, a polycrystalline silicon semiconductor, an oxide semiconductor, and/or the like.

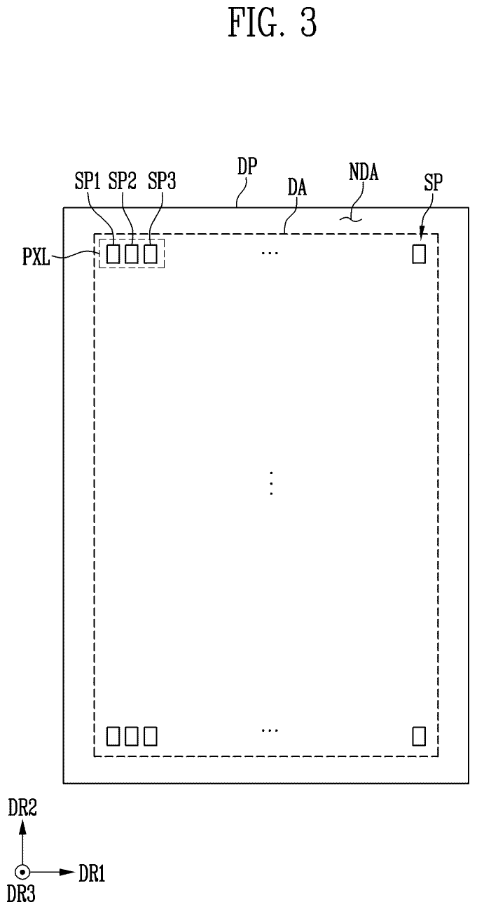

FIG. 3 is a plan view of a display panel according to some embodiments.

Referring to FIG. 3, a display panel DP may include a display area DA and a non-display area NDA. The display panel DP displays an image through the display area DA. The non-display area NDA may be disposed at the periphery of the display area DA.

The display panel DP may include sub-pixels SP in the display area DA. The sub-pixels SP may be arranged along a first direction DR1, and a second direction DR2 crossing or intersecting the first direction DR1. For example, the sub-pixels SP may be arranged in a matrix form along the first direction DR1 and the second direction DR2. In another example, the sub-pixels SP may be arranged in a zigzag form along the first direction DR1 and the second direction DR2. In some embodiments, the arrangement of the sub-pixels SP may vary. The first direction DR1 may be a row direction, and the second direction DR2 may be a column direction.

Two or more sub-pixels from among the sub-pixels SP may constitute one pixel PXL. In FIG. 3, the pixel PXL is illustrated as including three sub-pixels SP1 to SP3. However, the present disclosure is not limited thereto. For example, the pixel PXL may include two sub-pixels. Hereinafter, for convenience of illustration, the pixel PXL may be described in more detail as including the first to third sub-pixels SP1 to SP3.

Each of the first to third sub-pixels SP1 to SP3 may generate light of one of various suitable colors, such as red, green, blue, cyan, magenta, and/or yellow. Hereinafter, for convenience of illustration, the first sub-pixel SP1 may generate light of a red color, the second sub-pixel SP2 may generate light of a green color, and the third sub-pixel SP3 may generate light of a blue color, but the present disclosure is not limited thereto.

Each of the first to third sub-pixels SP1 to SP3 may include at least one light emitting element to generate light. In some embodiments, light emitting elements of the first to third sub-pixels SP1 to SP3 may generate light of the same color as each other. In some embodiments, the light emitting elements of the first to third sub-pixels SP1 to SP3 may generate light of a red color, a green color, and a blue color, respectively.

Self-luminous display panels, such as a light emitting diode display panel (LED display panel) that uses a light emitting diode of micro scale or nano scale as a light emitting element, and an organic light emitting display panel (OLED panel) that uses an organic light emitting diode as a light emitting element, may be used as the display panel DP.

A component for controlling the sub-pixels SP may be disposed in the non-display area NDA. Lines connected to the sub-pixels SP (e.g., the first to mth gate lines GL1 to GLm, the first to nth data lines DL1 to DLn, the power lines PL, and the pixel control lines PXCL described above with reference to FIG. 1) may be disposed in the non-display area NDA.

At least one of the gate driver 120, the data driver 130, the voltage generator 140, and/or the controller 150 described above with reference to FIG. 1 may be disposed in the non-display area NDA of the display panel DP. In some embodiments, the gate driver 120 may be disposed in the non-display area NDA. The data driver 150, the voltage generator 140, and the controller 150 may be implemented into the driver integrated circuit DIC described above with reference to FIG. 1, which is distinguished from the display panel DP. The driver integrated circuit DIC may be connected to the lines disposed in the non-display area NDA. In other embodiments, the gate driver 120, the data driver 130, the voltage generator 140, and the controller 150 may be implemented together into one integrated circuit distinguished from (e.g., that is separate from or different from) the display panel DP.

In some embodiments, the display area DA may have various suitable shapes. The display area DA may have a closed-loop shape including linear sides and/or curved sides. For example, the display area DA may have various suitable shapes, such as a polygon, a circle, a semicircle, and/or an ellipse.

In some embodiments, the display panel DP may have a flat or substantially flat display surface. In other embodiments, the display panel DP may have at least a partially round or rounded display surface. In some embodiments, the display panel DP may be bendable, foldable, or rollable. The display panel DP and/or a substrate of the display panel DP may include various suitable materials having a flexibility.

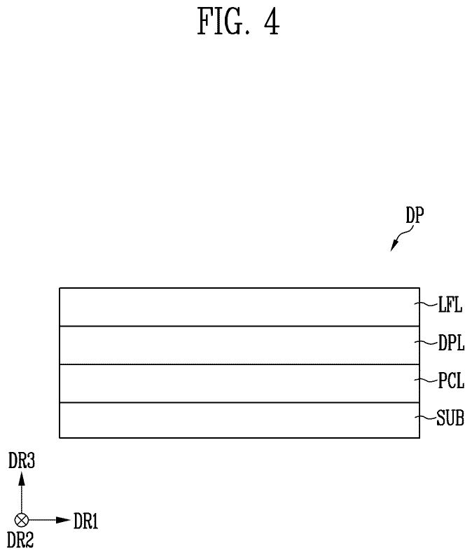

FIG. 4 is a sectional view of a display panel according to some embodiments.

Referring to FIG. 4, a display panel DP may include a substrate SUB. The display panel DP may further include a pixel circuit layer PCL, a display element layer DPL, and a light functional layer LFL, which are sequentially stacked in a third direction DR3 crossing or intersecting the first and second directions DR1 and DR2, on the substrate SUB.

The substrate SUB may include (e.g., may be made of) an insulative material, such as glass or a resin. For example, the substrate SUB may include a glass substrate. In another example, the substrate SUB may include a polyimide (PI) substrate. In another example, the substrate SUB may include a silicon wafer substrate formed using a semiconductor process.

In some embodiments, the substrate SUB may include (e.g., may be made of) a suitable material having a flexibility to be curvable or foldable, and may have a single-layer structure or a multi-layered structure. For example, the material having the flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate. However, the present disclosure is not limited thereto.

The pixel circuit layer PCL is disposed on the substrate SUB. The pixel circuit layer PCL may include one or more insulating layers, and semiconductor patterns and conductive patterns disposed between the insulating layers. The conductive patterns of the pixel circuit layer PCL may serve as the circuit elements, the lines, and the like.

The circuit elements of the pixel circuit layer PCL may include the sub-pixel circuit SPC (e.g., see FIG. 2) of each of the sub-pixels SP described above with reference to FIG. 3. In other words, the circuit elements of the pixel circuit layer PCL may be provided as the transistors and the one or more capacitors of the sub-pixel circuit SPC.

The lines of the pixel circuit layer PCL may include the lines connected to each of the sub-pixels SP. The lines of the pixel circuit layer PCL may include various suitable signal lines and/or various suitable voltage lines, which are used for driving the display element layer DPL.

The display element layer DPL may be disposed on the pixel circuit layer PCL. The display element layer DPL may include the light emitting elements of the sub-pixels SP.

The light functional layer LFL may be disposed on the display element layer DPL. The light functional layer LFL may include light conversion patterns having color conversion particles and/or light scattering particles. For example, the color conversion particles may include quantum dots. The quantum dots may change a wavelength (e.g., a color) of the light emitted from the display element layer DPL. The light functional layer LFL may include light scattering patterns having the light scattering particles. In some embodiments, the light conversion patterns and the light scattering patterns may be omitted.

The light functional layer LFL may further include a color filter layer including color filters. The color filter may allow light having a desired or specific wavelength (e.g., a desired or specific color) to be selectively transmitted therethrough. In some embodiments, the color filter layer may be omitted.

A window for protecting an exposed surface (e.g., a top surface) of the display panel DP may be provided on the light functional layer LFL. The window may protect the display panel DP from external impacts. The window may be bonded to the light functional layer LFL through an optically transparent adhesive (or cohesive) member. The window may have a multi-layered structure selected from a glass substrate, a plastic film, and/or a plastic substrate. The multi-layered structure may be formed through a continuous process, or an adhesive process using an adhesive layer. The whole (e.g., an entirety) or a portion of the window may have a flexibility.

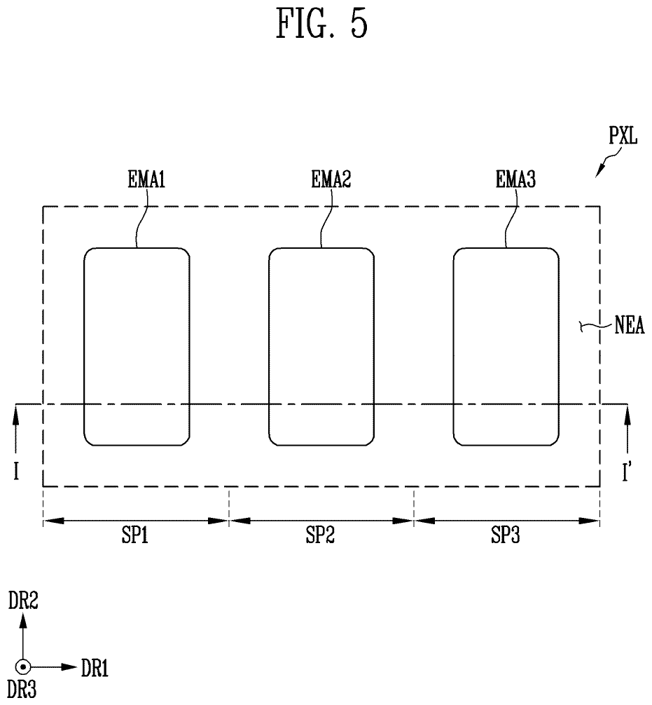

FIG. 5 is a plan view of a pixel according to some embodiments.

Referring to FIG. 5, the pixel PXL may include first to third sub-pixels SP1 to SP3 arranged along the first direction DR1.

The first sub-pixel SP1 may include a first emission area EMA1, and a non-emission area NEA at the periphery of the first emission area EMA1. The second sub-pixel SP2 may include a second emission area EMA2, and the non-emission area NEA at the periphery of the second emission area EMA2. The third sub-pixel SP3 may include a third emission area EMA3, and the non-emission area NEA at the periphery of the third emission area EMA3.

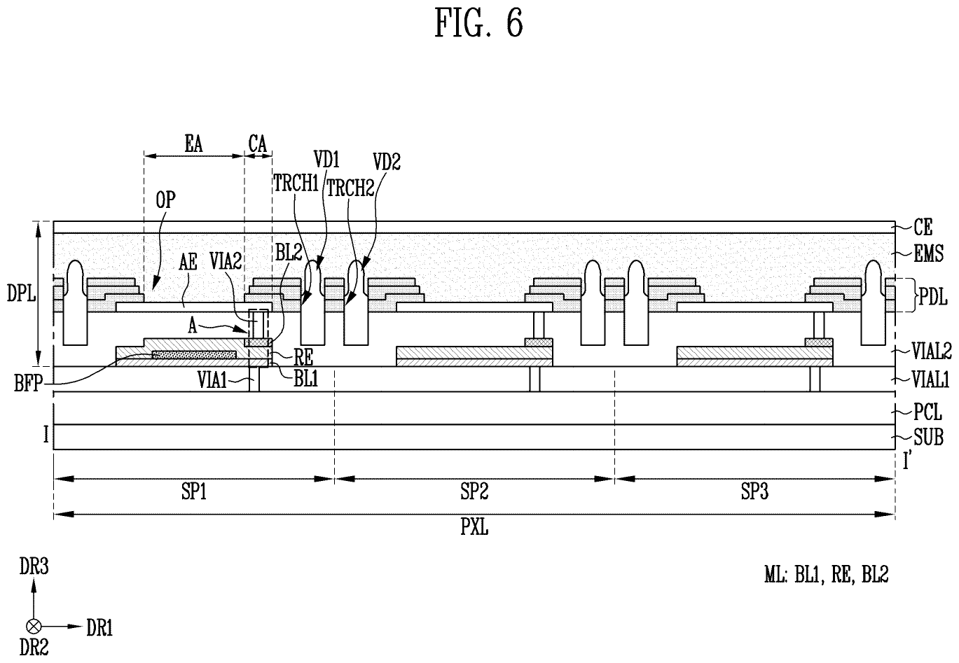

The first emission area EMA1 may be an area in which light is emitted from a portion of a light emitting structure EMS (e.g., see FIG. 6), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3.

FIG. 6 is a sectional view taken along the line I-I′ of FIG. 5 according to some embodiments.

Referring to FIG. 6, the pixel circuit layer PCL may be disposed on the substrate SUB.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The pixel circuit layer PCL may include insulating layers, semiconductor patterns, and conductive patterns, which are stacked on the substrate SUB. The insulating layers may include a buffer layer, one or more interlayer insulating layers, and one or more passivation layers. The semiconductor patterns and the conductive patterns may be located between the insulating layers. The conductive patterns may include at least one material from among copper (Cu), molybdenum (Mo), tungsten (W), aluminum neodymium (AlNd), titanium (Ti), aluminum (Al), and/or silver (Ag).

The pixel circuit layer PCL may include circuit elements of each of the first to third sub-pixels SP1 to SP3. For example, the pixel circuit layer PCL may include a transistor of the first sub-pixel SP1, a transistor of the second sub-pixel SP2, and a transistor of the third sub-pixel SP3. The transistor of the first sub-pixel SP1 may be referred to as a first transistor, the transistor of the second sub-pixel SP2 may be referred to as a second transistor, and the transistor of the third sub-pixel SP3 may be referred to as a third transistor. The first transistor may be any one of the transistors included in a sub-pixel SPC (e.g., see FIG. 2) of the first sub-pixel SP1, the second transistor may be any one of the transistors included in a sub-pixel SPC of the second sub-pixel SP2, and the third transistor may be any one of the transistors included in a sub-pixel SPC of the third sub-pixel SP3. The semiconductor patterns and the conductive patterns of the pixel circuit layer PCL may serve as the first to third transistors.

A first via layer VIAL1 may be disposed on the pixel circuit layer PCL. The first via layer VIAL1 covers the pixel circuit layer PCL, and may have an entirely flat or substantially flat surface. The first via layer VIAL1 may planarize or substantially planarize step differences on the pixel circuit layer PCL. The first via layer VIAL1 may include at least one of silicon oxide (SiOₓ), silicon nitride (SiNₓ), and/or silicon carbon nitride (SiCN), but the present disclosure is not limited thereto.

A first via VIA1 penetrating the first via layer VIAL1 may be provided in each of the first to third sub-pixels SP1 to SP3. In each of the first to third sub-pixels SP1 to SP3, the first via VIA1 may electrically connect a circuit element of the pixel circuit layer PCL and a mirror layer ML to each other. For example, in the first sub-pixel SP1, the first via VIA1 may electrically connect the first transistor and the mirror layer ML (e.g., a first mirror layer) to each other. In the second sub-pixel SP2, the first via VIA1 may electrically connect the second transistor and the mirror layer ML (e.g., a second mirror layer) to each other. In the third sub-pixel SP3, the first via VIA1 may electrically connect the third transistor and the mirror layer ML (e.g., a third mirror layer) to each other. In each of the first to third sub-pixels SP1 to SP3, one end of the first via VIA1 may be in contact with the pixel circuit layer PCL, and the other end of the first via VIA1 may be in contact with a first barrier layer BL1 of the mirror layer (e.g., the corresponding mirror layer) ML.

A display element layer DPL may be disposed on the first via layer VIAL1. The display element layer DPL may include the mirror layer ML provided in each of the first to third sub-pixels SP1 to SP3, a second via layer VIAL2, an anode AE provided in each of the first to third sub-pixels SP1 to SP3, a pixel defining layer PDL, a light emitting structure EMS, and a cathode CE.

In each of the first to third sub-pixels SP1 to SP3, the mirror layer ML may be disposed on the first via layer VIAL1. The mirror layer ML disposed in the first sub-pixel SP1 may be referred to as a first mirror layer, the mirror layer ML disposed in the second sub-pixel SP2 may be referred to as a second mirror layer, and the mirror layer ML disposed in the third sub-pixel SP3 may be referred to as a third mirror layer. The mirror layer ML may be in contact with a circuit element of the pixel circuit layer PCL through the first via VIA1. The mirror layer ML may include the first barrier layer BL1, a reflective electrode RE, and a second barrier layer BL2.

In each of the first to third sub-pixels SP1 to SP3, the first barrier layer BL1 may be disposed on the first via layer VIAL1. The first barrier layer BL1 may improve an electrical connection characteristic between the reflective electrode RE and the circuit element of the pixel circuit layer PCL. The first barrier layer BL1 may include at least one of titanium (Ti) and/or titanium nitride (TiN), but the present disclosure is not limited thereto. The first barrier layer BL1 may have a multi-layered structure. For example, the first barrier layer BL1 may have a multi-layered structure of Ti/TiN/Ti.

In each of the first to third sub-pixels SP1 to SP3, the reflective electrode RE may be disposed on the first barrier layer BL1. The reflective electrode RE disposed on the first barrier layer BL1 of the first sub-pixel SP1 may be referred to as a first reflective electrode, the reflective electrode RE disposed on the first barrier layer BL1 of the second sub-pixel SP2 may be referred to as a second reflective electrode, and the reflective electrode RE disposed on the first barrier layer BL1 of the third sub-pixel SP3 may be referred to as a third reflective electrode. The reflective electrode RE may serve as full mirrors that reflect light emitted from the light emitting structure EMS toward a display surface (e.g., toward a cover window). The reflective electrode RE may include a metal material suitable for reflecting light. The reflective electrode RE may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or any suitable alloys of two or more materials selected therefrom, but the present disclosure is not limited thereto.

In at least one of the first to third sub-pixels SP1 to SP3, a buffer pattern BFP may be disposed under the reflective electrode RE. The buffer pattern BFP may include an inorganic material such as silicon carbon nitride (SiCN), but the present disclosure is not limited thereto. The buffer pattern BFP may adjust a height of the reflective electrode RE in the third direction DR3. For example, the buffer pattern BFP may be disposed between the reflective electrode RE (e.g., a first reflective electrode) of the first sub-pixel SP1 and the first barrier layer BL1, to adjust a height of the reflective electrode RE (e.g., the first reflective electrode) of the first sub-pixel SP1.

The reflective electrode RE may serve as full mirrors, and the cathode CE may serve as a half mirror. Light emitted from a light emitting layer of the light emitting structure EMS may be amplified by at least partially reciprocating between the reflective electrode RE and the cathode CE, and the amplified light may be output through the cathode CE. As such, a distance between the reflective electrode RE and the cathode CE may be understood as a resonance distance of the light emitted from the light emitting layer of the corresponding light emitting structure EMS.

Because of the buffer pattern BFP, the first sub-pixel SP1 may have a resonance distance shorter than resonance distances of the second and third sub-pixels SP2 and SP3. Light in a specific or predetermined wavelength range (e.g., a red color) may be effectively and efficiently amplified by the adjusted resonance distance. Accordingly, the first sub-pixel SP1 may effectively and efficiently output light of the corresponding wavelength range.

In FIG. 6, the buffer pattern BFP is illustrated as being provided to the first sub-pixel SP1, and is not provided to the second and third sub-pixels SP2 and SP3. However, the present disclosure is not limited thereto. The buffer pattern may be provided even in at least one of the second and/or third sub-pixels SP2 and SP3, to adjust a resonance distance of the at least one of the second and/or third sub-pixels SP2 and SP3. For example, a distance between the reflective electrode RE (e.g., the first reflective electrode) of the first sub-pixel SP1 and the cathode CE may be shorter than a distance between the reflective electrode RE (e.g., a second reflective electrode) of the second sub-pixel SP2 and the cathode CE, and the distance between the reflective electrode RE (e.g., the second reflective electrode) of the second sub-pixel SP2 and the cathode CE may be shorter than a distance between the reflective RE (e.g., a third reflective electrode) of the third sub-pixel SP3 and the cathode CE.

In each of the first to third sub-pixels SP1 to SP3, the second barrier layer BL2 may be disposed on a portion of the reflective electrode RE. In some embodiments, the second barrier layer BL2 may be disposed on a portion of the reflective electrode RE overlapping with a contact area CA of the anode AE. For example, a width of the second barrier layer BL2 in the first direction DR1 may be equal to or substantially equal to a width of the contact area CA, but the present disclosure is not limited thereto. Unlike that described above with reference to FIG. 6, the second barrier layer BL2 may overlap with a portion of the contact area CA of the anode AE. For example, the width of the second barrier BL2 in the first direction DR1 may be smaller than the width of the contact area CA of the anode AE.

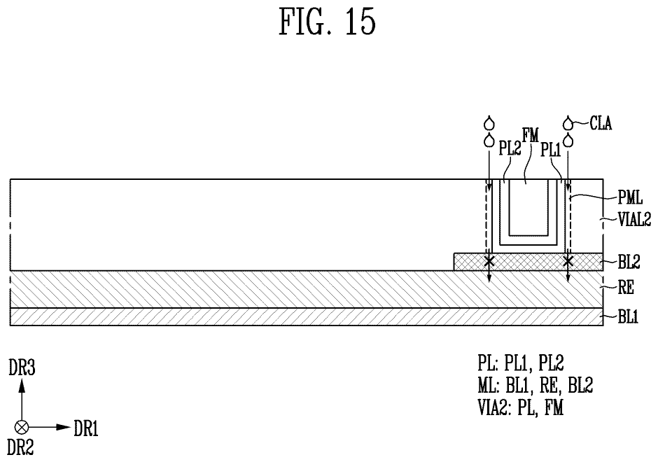

The second barrier layer BL2 may prevent or substantially prevent an external material from being introduced into the reflective electrode RE. In other words, the second barrier layer BL2 may block the reflective electrode RE from being in contact with the external material. For example, the second barrier layer BL2 may prevent or substantially prevent the reflective electrode RE from being melted by blocking a cleaning agent CLA (e.g., see FIG. 15) from being introduced into the reflective electrode RE. The second barrier layer BL2 may include titanium nitride (TiN), but the present disclosure is not limited thereto.

The second via layer VIAL2 may be disposed on the first via layer VIAL1 and the reflective electrodes RE to planarize or substantially planarize step differences between the reflective electrodes RE. The second via layer VIAL2 may entirely cover the reflective electrodes RE and the first via layer VIAL1, and may have a flat or substantially flat surface. The second via layer VIAL2 may include at least one of silicon oxide (SiOₓ), silicon nitride (SiNₓ), and/or silicon carbon nitride (SiCN), but the present disclosure is not limited thereto.

A second via VIA2 penetrating the second via layer VIAL2 may be provided in each of the first to third sub-pixels SP1 to SP3. For example, the second via VIA2 may penetrate a portion of the second via layer VIAL2, which overlaps with the contact area CA of the anode AE. In each of the first to third sub-pixels SP1 to SP3, the second via VIA2 may electrically connect the mirror layer ML and the anode AE to each other. For example, in the first sub-pixel SP1, the second via VIA2 may electrically connect the mirror layer ML (e.g., the first mirror layer) and the anode AE (e.g., a first anode) to each other. In the second sub-pixel, the second via VIA2 may electrically connect the mirror layer ML (e.g., the second mirror layer) and the anode AE (e.g., the second anode) to each other. In the third sub-pixel SP3, the second via VIA2 may electrically connect the mirror layer ML (e.g., the third mirror layer) and the anode AE (e.g., the third anode) to each other. In each of the first to third sub-pixels SP1 to SP3, one end of the second via VIA2 may be in contact with the second barrier layer BL2 of the mirror layer ML, and another end (e.g., an opposite end) of the second via VIA2 may be in contact with the anode AE.

In each of the first to third sub-pixels SP1 to SP3, the anode AE overlapping with the reflective electrode RE may be disposed on the second via layer VIAL2. The anode AE disposed in the first sub-pixel SP1 may be referred to as the first anode, the anode AE disposed in the second sub-pixel SP2 may be referred to as the second anode, and the anode AE disposed in the third sub-pixel SP3 may be referred to as the third anode.

The anode AE may include an exposure area EA (e.g., an emission area) and the contact area CA. The exposure area EA may refer to a portion of the anode AE, which is exposed by an opening OP of the pixel defining layer PDL. The contact area CA may refer to a portion of the anode AE, which is located at one side of the exposure area EA, is covered by the pixel defining layer PDL, and is provided to be connected to the second via VIA2. In the contact area CA, the anode AE may be electrically connected to the reflective electrode RE. For example, the anode AE may be electrically connected to the reflective electrode RE through the second via VIA2 and the second barrier BL2, which overlap with the contact area CA.

The anode AE may include at least one of various suitable transparent conductive materials, such as indium tin oxide (ITO), indium zinc oxide (IZO), zinc oxide (ZnO), indium gallium zinc oxide (IGZO), and/or indium tin zinc oxide (ITZO). However, the material of the anode AE is not limited thereto. For example, the anode AE may include titanium nitride (TiN).

The pixel defining layer PDL may be disposed on portions of the anodes AE and the second via layer VIAL2. The pixel defining layer PDL may include the opening OP exposing a portion of each of the anodes AE. The opening OP of the pixel defining layer PDL may define an emission area of each of the first to third sub-pixels SP1 to SP3. For example, the pixel defining layer PDL may define the first to third emission areas EMA1 to EMA3 described above with reference to FIG. 5, while being disposed in the non-emission area NEA described above with reference to FIG. 5.

The pixel defining layer PDL may include a plurality of inorganic insulating layers. Each of the inorganic insulating layers may include at least one of silicon oxide (SiOₓ) and/or silicon nitride (SiNₓ). For example, the pixel defining layer PDL may include first to third inorganic insulating layers that are sequentially stacked. The first to third inorganic insulating layers may include silicon nitride, silicon oxide, and silicon nitride, respectively. However, the present disclosure is not limited thereto. The first to third inorganic insulating layers may have a stepped section in an area adjacent to the opening OP of the pixel defining layer PDL.

A separator may be provided in a boundary area between the sub-pixels that are adjacent to each other. The separator may cause a discontinuity to be formed in the light emitting structure EMS in the boundary area. For example, the light emitting structure EMS may be cut or bent by the separator in the boundary area.

The separator may be provided in the pixel defining layer PDL. The pixel defining layer PDL may include one or more trenches TRCH1 and TRCH2 as the separator. As shown in FIG. 6, the one or more trenches TRCH1 and TRCH2 may penetrate the pixel defining layer PDL, and may partially penetrate the second via layer VIA2. However, the present disclosure is not limited thereto. For example, the one or more trenches TRCH1 and TRCH2 may penetrate the pixel defining layer PDL and the second via layer VIAL2, and may partially penetrate the first via layer VIAL1. For example, the one or more trenches TRCH1 and TRCH2 may at least partially penetrate the second via layer VIAL2 and/or the first via layer VIAL1, and a portion of the pixel defining layer PDL may be disposed in the one or more trenches TRCH1 and TRCH2.

In FIG. 6, the pixel defining layer PDL is illustrated as including two trenches TRCH1 and TRCH2 in the boundary area. However, the present disclosure is not limited thereto. For example, the pixel defining layer PDL may include one trench in the boundary area. As another example, the pixel defining layer PDL may include three or more trenches in the boundary area.

Due to first and second trenches TRCH1 and TRCH2, discontinuities such as a first void VD1 and a second void VD2 may be formed in the light emitting structure EMS in the boundary area. Some of a plurality of layers that are stacked in the light emitting structure EMS may be cut or bent by the first and second voids VD1 and VD2. For example, at least one charge generation layer included in the light emitting structure EMS may be cut by the first and second voids VD1 and VD2. As such, due to the first and second trenches TRCH1 and TRCH2, portions of the light emitting structure EMS included in the first to third sub-pixels SP1 to SP3 may be at least partially separated from each other.

In FIG. 6, the first and second voids VD1 and VD2 are illustrated as formed in the light emitting structure EMS in the boundary area. However, the present disclosure is not limited thereto. For example, a concave-shaped valley may be formed in the light emitting structure EMS in the boundary area. The discontinuities formed in the light emitting structure EMS may be variously modified according to the shapes of the first and second trenches TRCH1 and TRCH2.

The light emitting structure EMS may be disposed on the anodes AE exposed by the openings OP of the pixel defining layer PDL. The light emitting structure EMA fills the openings OP of the pixel defining layer PDL, and may be entirely disposed throughout the first to third pixels SP1 to SP3. As described above, the light emitting structure EMS may be at least partially cut or bent by the separator in the boundary area. Accordingly, in an operation of the display panel DP (e.g., see FIG. 3), a current leaked from each of the first to third sub-pixels SP1 to SP3 to a sub-pixel adjacent thereto through the layers included in the light emitting structure EMS may be decreased. Thus, the display panel DP may operate with a relatively high reliability.

The cathode CE may be disposed over the light emitting structure EMS. The cathode CE may be commonly provided in the first to third sub-pixels SP1 to SP3. The cathode CE may serve as a half mirror to allow light emitted from the light emitting structure EMS to be partially transmitted therethrough and to be partially reflected therefrom.

The exposure area EA of the anode (e.g., the first anode) of the first sub-pixel SP1, a portion of the light emitting structure EMS, which overlaps with the exposure area EA, and a portion of the cathode CE, which overlaps with the exposure area EA, may constitute a light emitting element (e.g., the first light emitting element) of the first sub-pixel SP1. The exposure area EA of the anode (e.g., the second anode) of the second sub-pixel SP2, a portion of the light emitting structure EMS, which overlaps with the exposure area EA, and a portion of the cathode CE, which overlaps with the exposure area EA, may constitute a light emitting element (e.g., the second light emitting element) of the second sub-pixel SP2. The exposure area EA of the anode (e.g., the third anode) of the third sub-pixel SP3, a portion of the light emitting structure EMS, which overlaps with the exposure area EA, and a portion of the cathode CE, which overlaps with the exposure area EA, may constitute a light emitting element (e.g., the third light emitting element) of the third sub-pixel SP3.

An encapsulation layer may be disposed over the cathode CE. The encapsulation layer may prevent or substantially prevent oxygen and/or moisture from infiltrating into the display element layer DPL.

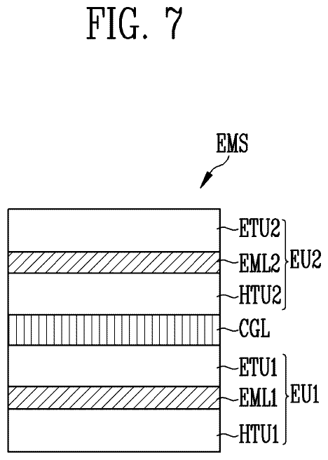

FIG. 7 is a sectional view of a light emitting structure according to some embodiments.

Referring to FIG. 7, the light emitting structure EMS may have a tandem structure in which first and second light emitting units EU1 and EU2 are stacked. The light emitting structure EMS may be configured the same or substantially the same in each of light emitting elements (e.g., the first to third light emitting elements) of the first to third sub-pixels SP1 to SP3 (e.g., see FIG. 6).

Each of the first and second light emitting units EU1 and EU2 may include at least one light emitting layer for generating light according to an applied current. The first light emitting unit EU1 may include a first light emitting layer EML1, a first electron transport unit (e.g., a first electron transport layer) ETU1, and a first hole transport unit (e.g., a first hole transport layer) HTU1. The first light emitting layer EML1 may be disposed between the first electron transport unit ETU1 and the first hole transport unit HTU1. The second light emitting unit EU2 may include a second light emitting layer EML2, a second electron transport unit (e.g., a second electron transport layer) ETU2, and a second hole transport unit (e.g., a second hole transport layer) HTU2. The second light emitting layer EML2 may be disposed between the second electron transport unit ETU2 and the second hole transport unit HTU2.

Each of the first and second hole transport units HTU1 and HTU2 may include at least one of a hole injection layer and/or a hole transport layer. Each of the first and second hole transport units HTU1 and HTU2 may further include a hole buffer layer, an electron blocking layer, and the like, if necessary or desired. The first and second hole transport units HTU1 and HTU2 may have the same or substantially the same configuration as each other, or may have different configurations from each other.

Each of the first and second electron transport units ETU1 and ETU2 may include at least one of an electron injection layer and/or an electron transport layer. Each of the first and second electron transport units ETU1 and ETU2 may further include an electron buffer layer, a hole blocking layer, and the like, if necessary or desired. The first and second electron transport units ETU1 and ETU2 may have the same or substantially the same configuration as each other or may have different configurations from each other.

A connection layer, which may be provided in the form of a charge generation layer CGL, may be disposed between the first light emitting unit EU1 and the second light emitting unit EU2 to connect the first light emitting unit EU1 and the second light emitting unit EU2 to each other. The charge generation layer CGL may have a stacked structure of a p-dopant layer and an n-dopant layer. For example, the p-dopant layer may include a p-type dopant, such as HAT-CN, TCNQ, or NDP-9, and the n-dopant layer may include an alkali metal, an alkali earth metal, a lanthanide-based metal, or any suitable combination thereof. However, the present disclosure is not limited thereto.

The first light emitting layer EML1 and the second light emitting layer EML2 may generate light of different colors from each other. The light respectively emitted from the first light emitting layer EML1 and the second light emitting layer EML2 may be mixed together to be viewed as white light. For example, the first light emitting layer EML1 may generate light of a blue color, and the second light emitting layer EML2 may generate light of a yellow color. The second light emitting layer EML2 may include a structure in which a first sub-light emitting layer to generate light of a red color and a second sub-light emitting layer to generate light of a green color are stacked. The light of the red color and the light of the green color may be mixed together to provide light of a yellow color. An intermediate layer configured to perform a function of transporting holes and/or a function of blocking transportation of electrodes may be further disposed between the first and second sub-light emitting layers. However, the present disclosure is not limited thereto. For example, the first light emitting layer EML1 and the second light emitting layer EML2 may generate light of the same or substantially the same color as each other.

The light emitting structure EMS may be formed through a suitable process, such as vacuum deposition or inkjet printing, but the present disclosure is not limited thereto.

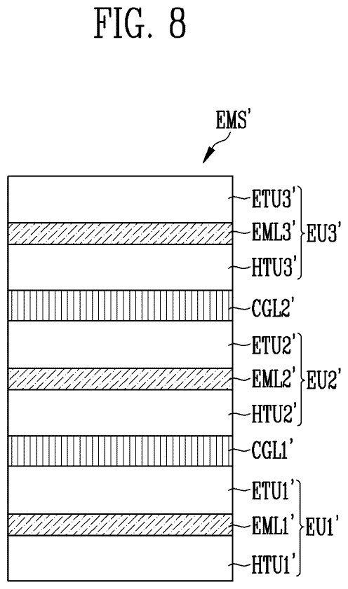

FIG. 8 is a sectional view of a light emitting structure according to some embodiments.

Referring to FIG. 8, the light emitting structure EMS′ may have a tandem structure in which first to third light emitting units EU1′ to EU3′ are stacked. The light emitting structure EMS′ may be configured the same or substantially the same in each of the light emitting elements (e.g., the first to third light emitting elements) of the first to third sub-pixels SP1 to SP3 (e.g., see FIG. 6).

Each of the first to third light emitting units EU1′ to EU3′ may include a light emitting layer for generating light according to an applied current. The first light emitting unit EU1′ may include a first light emitting layer EML1′, a first electron transport unit (e.g., a first electron transport layer) ETU1′ and a first hole transport unit (e.g., a first hole transport layer) HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit (e.g., a second electron transport layer) ETU2′, and a second hole transport unit (e.g., a second hole transport layer) HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit (e.g., a third electron transport layer) ETU3′, and a third hole transport unit (e.g., a third hole transport layer) HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and/or a hole transport layer, and may further include a hole buffer layer, an electron blocking layer, and/or the like, if necessary or desired. The first to third hole transport units HTU1′ to HTU3′ may have the same or substantially the same configuration as each other, or may have different configurations from one another.

Each of the first to third electron transport units ETU1′ to ETU3′ may include at least one of an electron injection layer and/or an electron transport layer, and may further include an electron buffer layer, a hole blocking layer, and/or the like, if necessary or desired. The first to third electron transport units ETU1′ to ETU3′ may have the same or substantially the same configuration as each other, or may have different configurations from each other.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

The first to third light emitting layers EML1′ to EML3′ may generate light of different colors from each other. The light respectively emitted from the first to third light emitting layers EML1′ to EML3′ may be mixed together to be viewed as white light. For example, the first light emitting layer EML1′ may generate light of a blue color, the second light emitting layer EML2′ may generate light of a green color, and the third light emitting layer EML3′ may generate light of a red color. However, the present disclosure is not limited thereto. For example, two or more light emitting layers from among the first to third light emitting layers EML1′ to EML3′ may generate light of the same color as each other.

Unlike that described above with reference to FIGS. 7 and 8, the light emitting structure EMS described above with reference to FIG. 6 may include one light emitting unit in each of the first to third light emitting elements. The light emitting unit included in each of the first to third light emitting elements may be configured to emit light of different colors from each other. For example, a light emitting unit of the first light emitting element may emit light of a red color, a light emitting unit of the second light emitting element may emit light of a green color, and a light emitting unit of the third light emitting element may emit light of a blue color. Unlike that described above with reference to FIG. 6, the light emitting units of the first to third sub-pixels SP1 to SP3 may be spaced apart (e.g., may be separated) from each other, and each of the light emitting units may be disposed in a corresponding opening OP of the pixel defining layer PDL.

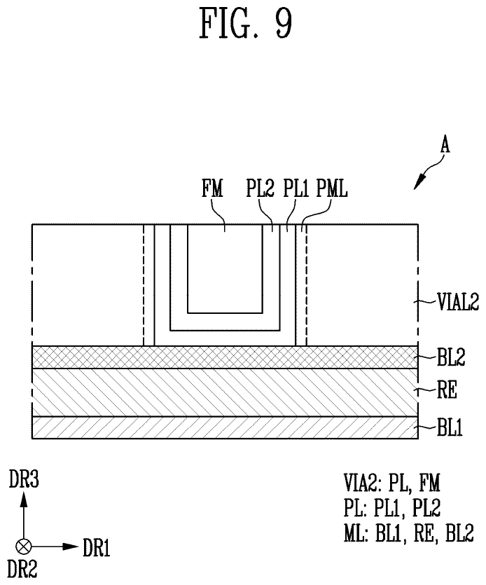

FIG. 9 is an enlarged view of the area A of FIG. 6.

Referring to FIG. 9, the second via VIA2 may include a protective layer PL and a filler FM.

The protective layer PL may be disposed on the second barrier layer BL2 of the mirror layer ML. The protective layer PL may be surrounded (e.g., around a periphery thereof) by the second via layer VIAL2. For example, a side surface of the protective layer PL may be in contact with the second via layer VIAL2. The protective layer PL may have a concave portion in which the filter FM may be filled. In other words, a section of the protective layer PL may have a concave shape.

The protective layer PL may block the filler FM from being in contact with an external material. For example, the protective layer PL may prevent or substantially prevent oxidation of the filler FM due to moisture, oxygen, and/or the like. In order to reinforce a blocking performance, the protective layer PL may have a multi-layered structure. For example, the protective layer PL may include a first protective layer PL1 and a second protective layer PL2. The first protective layer PL1 may be disposed on the second barrier layer BL2 of the mirror layer ML, and may have a first concave portion. The first protective layer PL1 may include titanium (Ti), but the present disclosure is not limited thereto. The second protective layer PL2 may fill the first concave portion of the first protective layer PL1. In other words, the second protective layer PL2 may be disposed on the first concave portion of the first protective layer PL1, and may have a second concave portion. The second protective layer PL2 may include titanium nitride (TiN), but the present disclosure is not limited thereto.

The filler FM may fill the concave portion of the protective layer PL. In other words, the filter FM may be disposed on the concave portion of the protective layer PL. When the protective layer PL has a multi-layered structure including the first protective layer PL1 and the second protective layer PL2, the filler FM may be disposed on the second concave portion of the second protective layer PL2. The filler FM may include a conductive material, such as tungsten (W), copper (Cu), or aluminum (Al).

A polymer layer PML generated in a process of forming the second via VIA2 may be located at the periphery of the second via layer VIAL2. For example, the polymer layer PML may be located between the second via layer VIAL2 and the protective layer PL. The polymer layer PML may be removed through a cleaning process which will be described in more detail below. In FIG. 9, the polymer layer PML is indicated by a dotted line for convenience of illustration, to show that the polymer layer PML has been removed. In other words, the second via VIA2 may not include the polymer layer PML.

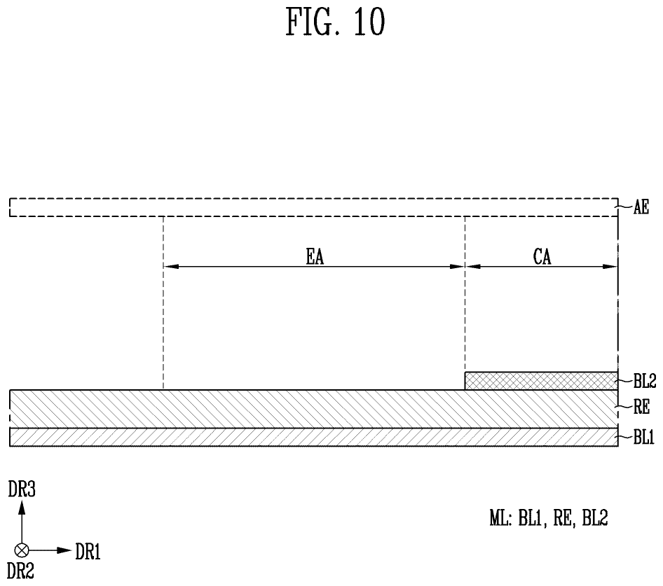

FIGS. 10 through 15 are sectional views of a method of manufacturing a display device according to some embodiments.

FIG. 10 schematically illustrates a process of forming the mirror layer ML. Referring to FIG. 10, a reflective electrode RE is formed on a first barrier layer BL1, and a second barrier layer BL2 may be formed on a portion of the reflective electrode RE. In more detail, the barrier layer BL2 may be formed on the reflective electrode RE overlapping with a contact area CA of the anode AE. The second barrier layer BL2 may not be formed on the reflective electrode RE overlapping with an exposure area EA of the anode AE. For example, the second barrier layer BL2 may be entirely formed on the reflective electrode RE. Afterwards, the second barrier layer BL2, except a portion overlapping with the contact area CA of the anode AE, may be removed using a mask, thereby forming the second barrier layer BL2 overlapping with the contact area CA of the anode AE. FIG. 10 shows that the contact area CA of the anode AE and the second barrier layer BL2 completely overlap with each other. However, the present disclosure is not limited thereto. For example, the second barrier layer BL2 may be formed to partially overlap with the contact area CA of the anode AE within a suitable range in which the second barrier layer BL2 does not overlap with the exposure area EA of the anode AE.

FIGS. 11 through 14 schematically illustrate a method of forming the second via VIA2. Referring to FIG. 11, after a second via layer VIAL2 is formed on the reflective electrode RE and the second barrier layer BL2, the second via layer VIAL2 on the second barrier layer BL2 may be partially removed, thereby forming a via hole VH. For example, the via hole VH may be formed through a Chemical Mechanical Polishing (CMP) process. In a process of forming the via hole VH, a polymer layer PML including a particle, a polymer, an impurity, and/or the like, which may be generated in the CMP process, may be formed at the periphery of the second via layer VIAL2. The polymer layer PML may be an unnecessary thin film, and may be removed through a cleaning process described in more detail below.

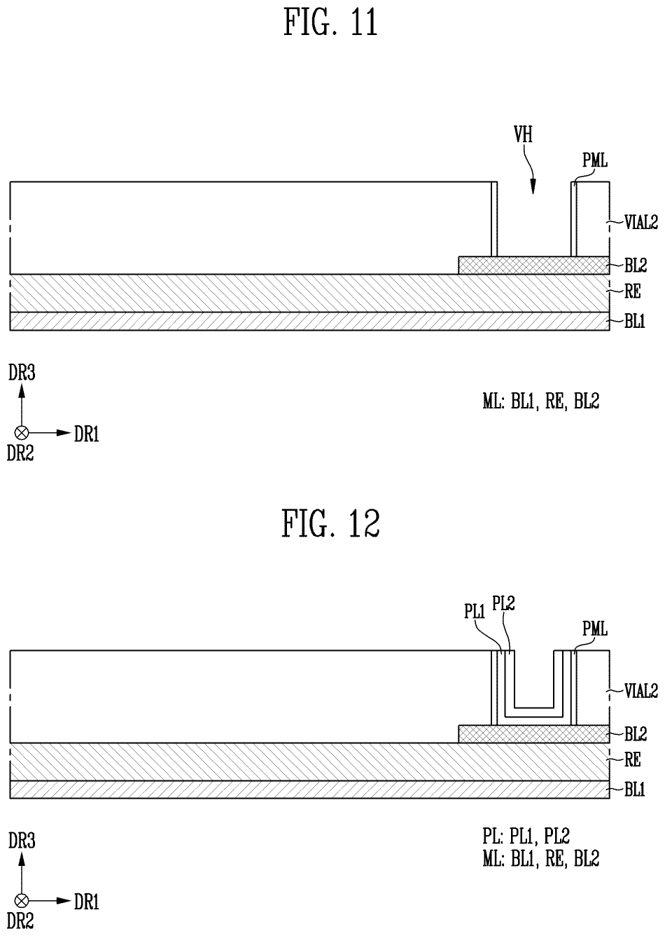

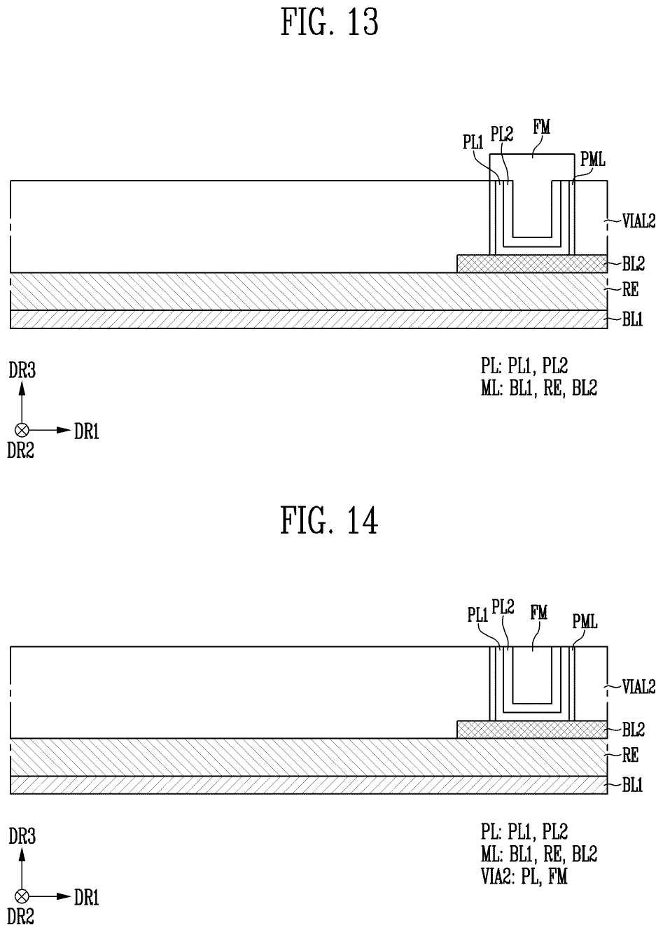

Referring to FIG. 12, the via hole VH (e.g., see FIG. 11) may be filled with a protective layer PL having a multi-layered structure with a concave portion. For example, the via hole VH may be filled with a first protective layer PL1 having a first concave portion. Afterwards, the first concave portion of the first protective layer PL1 may be filled with a second protective layer PL2 with a second concave portion. The protective layer PL may prevent or substantially prevent the filler FM (e.g., see FIG. 13) from being in contact with the polymer layer PML.

Referring to FIG. 13, the concave portion of the protective layer PL may be filled with the filler FM. For example, the second concave portion of the second protective layer PL2 may be filled with the filler FM. In a process of filling the filler FM, the filler FM may be located on the first protective layer PL1, the second protective layer PL2, and the polymer layer PML.

Referring to FIG. 14, a protrusion portion (e.g., see FIG. 13) of the filler FM may be removed. For example, the protrusion portion of the filler FM may be removed through a CMP process. Accordingly, upper surfaces of the protective layer PL, the polymer layer PML, and the filter FM may have a flat or substantially flat surface. In addition, the second via VIA2 including the protective layer PL and the filler FM may be formed.

FIG. 15 schematically illustrates a cleaning process. Referring to FIG. 15, the polymer layer PML generated in the CMP process may be removed using a cleaning agent CLA. The cleaning agent CLA may include hydrogen fluoride (HF), but the present disclosure is not limited thereto. The cleaning agent CLA may be introduced into the polymer layer PML to remove the polymer layer PML. In FIG. 15, the polymer layer PML is indicated by a dotted line for convenience of illustration, which shows that the polymer layer PML has been removed. The cleaning agent CLA may not be introduced into the reflective electrode RE due to the second barrier layer BL2. In other words, the barrier layer BL2 may block the cleaning agent CLA from being introduced into the reflective electrode RE. When the second barrier layer BL2 is not disposed on the reflective electrode RE, the reflective electrode RE may be melted as the cleaning agent CLA is introduced into the reflective electrode RE in the cleaning process. In the present embodiment, the second barrier layer BL2 may be formed on the reflective electrode RE corresponding to a position of the second via VIA2, thereby preventing or substantially preventing the reflective electrode RE from being melted by the cleaning agent CLA.

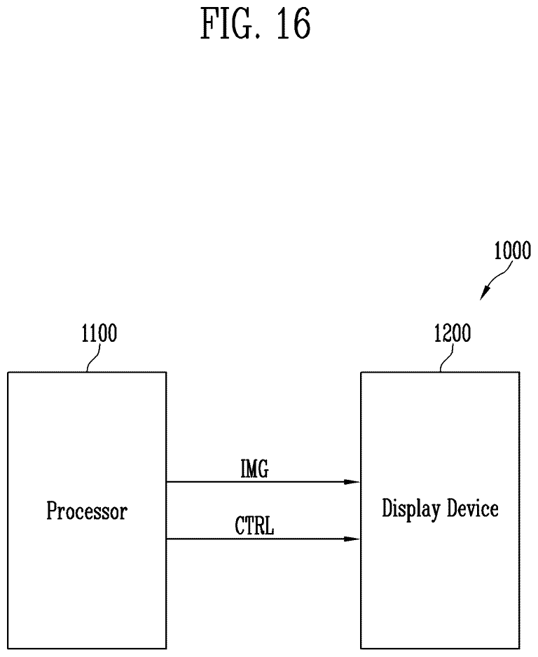

FIG. 16 is a block diagram of a display system according to some embodiments.

Referring to FIG. 16, the display system 1000 may include a processor 1100 and a display device 1200.

The processor 1100 may perform various suitable tasks and various suitable calculations. In some embodiments, the processor 1100 may include an Application Processor (AP), a Graphics Processing Unit (GPU), a microprocessor, a Central Processing Unit (CPU), and/or the like. The processor 1100 may be connected to the other components of the display system 1000 through a bus system to control the components of the display system 1000.

The processor 1100 may transmit image data IMG and a control signal CTRL to the display device 1200. The display device 1200 may display an image based on the image data IMG and the control signal CTRL. The display device 1200 may be configured the same or substantially the same as the display device DD described above with reference to FIG. 1. The image data IMG and the control signal CTRL may be provided as the input image data IMG and the control signal CTRL described above with reference to FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and/or an augmented reality (AR) device.

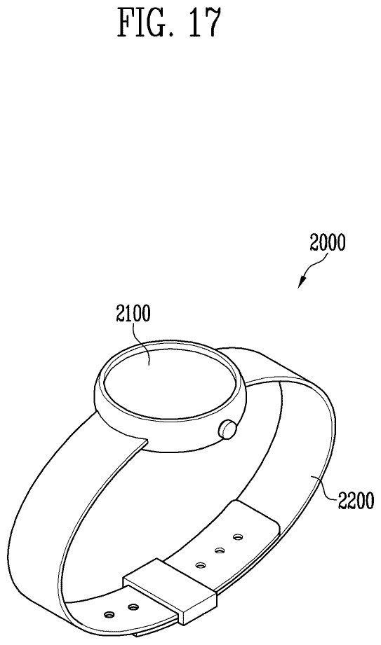

FIGS. 17 through 20 are perspective views of some application examples of the display system of FIG. 16.

Referring to FIG. 17, the display system 1000 described above with reference to FIG. 16 may be applied to a smart watch 2000 including a display part 2100 and a strap part 2200.

The smart watch 2000 may be a wearable electronic device. For example, the smart watch 2000 may have a suitable structure in which the strap part 2200 is mounted on a wrist of a user. The display system 1000 and/or the display device 1200 may be applied to the display part 2100, such that image data including time information may be provided to the user.

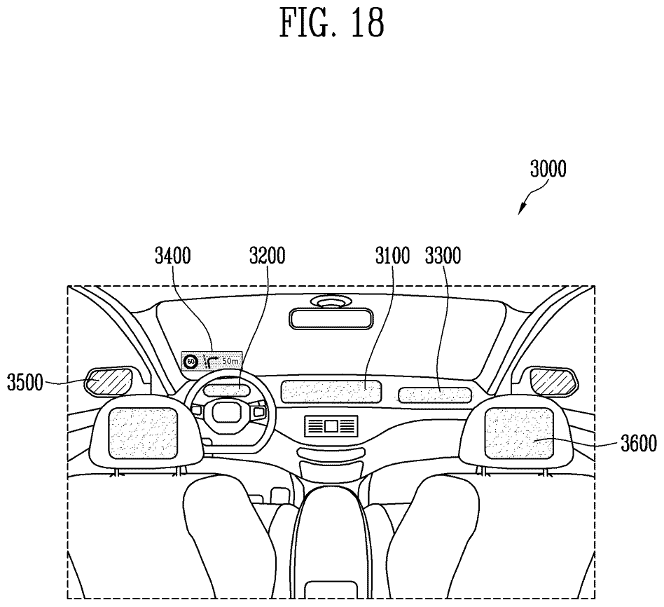

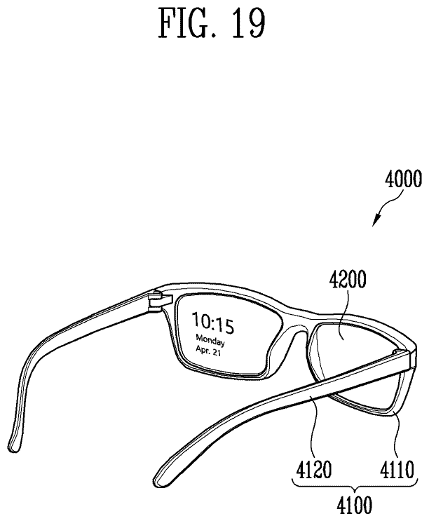

Referring to FIG. 18, the display system 1000 described above with reference to FIG. 16 may be applied to an automotive display system 3000. The automotive display system 3000 may include a computing system provided at the inside/outside of a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and/or a read seat display 3600, which are provided in the vehicle.

Referring to FIG. 19, the display system 1000 described above with reference to FIG. 16 may be applied to smart glasses 4000. The smart glasses 4000 may be a wearable electronic device that can be worn on the face of a user. For example, the smart glasses 4000 may be a wearable device for augmented reality (AR).

The smart glasses 4000 may include a frame 4100 and a lens part 4200. The frame 4100 may include a housing 4110 for supporting the lens part 4200, and a leg part 4120 for allowing the user to wear the smart glasses 4000. The leg part 4120 may be connected to the housing 4110 through a hinge to be folded or unfolded with respect to the housing 4110.

A battery, a touch pad, a microphone, a camera, and/or the like may be built in the frame 4100. In addition, a projector for outputting light, a processor for controlling a light signal, and/or the like may be built in the frame 4100.

The lens part 4200 may be an optical member that allows light to be transmitted therethrough, or allows light to be reflected thereby. For example, the lens part 4200 may include glass, a transparent synthetic resin, and/or the like.

In order to enable the eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

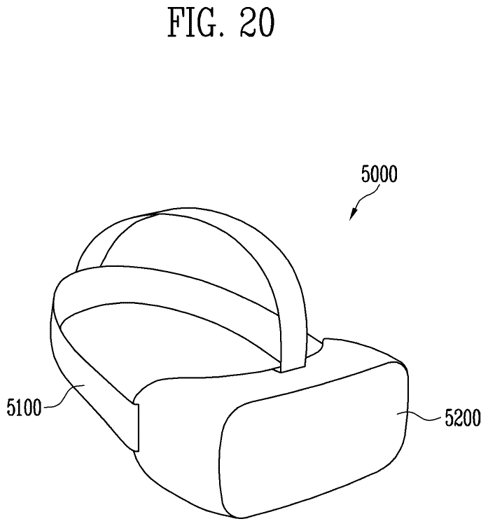

Referring to FIG. 20, the display system 1000 described above with reference to FIG. 16 may be applied to a head mounted display device 5000.

The head mounted display device 5000 may be a wearable electronic device that can be worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band that is used to fix the head mounted display device 5000 to the head of the user. The horizontal band may be configured to surround (e.g., around a periphery of) a side portion of the head of the user, and the vertical band may be configured to surround (e.g., around a periphery of) an upper portion of the head of the user. However, the present disclosure is not limited thereto. For example, the head mounted band 5100 may be implemented in the form of a glasses frame, a helmet, or the like.

The display device accommodating case 5200 may accommodate the display system 1000 and/or the display device 1200.

According to some embodiments, a display device and a method of manufacturing the display device, which may prevent damage of an anode, may be provided.

However, the aspects and features of the present disclosure are not limited to those described above, and various other aspects and features as would be understood by those having ordinary skill in the art may be included in the present disclosure.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

what is claimed is:

1. A display device, comprising:
an anode comprising an exposure area and a contact area;
a mirror layer overlapping with the anode; and
a via located between the anode and the mirror layer,
wherein the mirror layer comprises:
a first barrier layer;
a reflective electrode on the first barrier layer; and
a second barrier layer on a portion of the reflective electrode.

2. The display device according to claim 1, wherein the second barrier layer overlaps with the contact area.

3. The display device according to claim 2, wherein one end of the via is in contact with the second barrier layer, and another end of the via is in contact with the contact area.

4. The display device according to claim 1, wherein the second barrier layer comprises titanium nitride.

5. The display device according to claim 1, wherein the second barrier layer does not overlap with the exposure area.

6. The display device according to claim 1, wherein the reflective electrode comprises aluminum.

7. The display device according to claim 1, wherein the first barrier layer comprises at least one of titanium or titanium nitride.

8. The display device according to claim 1, wherein the via comprises:
a protective layer on the second barrier layer, and having a concave portion; and
a filler filling the concave portion.

9. The display device according to claim 8, wherein the protective layer comprises:
a first protective layer on the second barrier layer, the first protective layer having a first concave portion; and
a second protective layer on the first concave portion, the second protective layer having a second concave portion.

10. The display device according to claim 8, wherein the filler comprises tungsten.

11. A method of manufacturing a display device, the method comprising:
forming a second barrier layer on a portion of a reflective electrode, the reflective electrode being disposed on a first barrier layer;
forming a via layer covering the reflective electrode and the second barrier layer;
forming a via penetrating the via layer on the second barrier layer, and generating a polymer layer; and
removing the polymer layer.

12. The method according to claim 11, wherein the second barrier layer is formed at a position overlapping with a contact area of an anode.

13. The method according to claim 12, wherein the second barrier layer is not formed at a position overlapping with an exposure area of the anode.

14. The method according to claim 11, wherein the second barrier layer comprises titanium nitride.

15. The method according to claim 11, wherein the forming of the via comprises:
forming a via hole by removing a portion of the via layer on the second barrier layer;
filling the via hole with a protective layer having a concave portion; and
filling the concave portion with a filler.

16. The method according to claim 15, wherein the via layer is removed through a chemical mechanical polishing process.

17. The method according to claim 15, wherein the filling of the via hole with the protective layer comprises:
filling the via hole with a first protective layer having a first concave portion; and
filling the first concave portion with a second protective layer having a second concave portion.

18. The method according to claim 15, wherein the filler comprises tungsten.

19. The method according to claim 12, wherein the polymer layer is removed by a cleaning agent.

20. The method according to claim 19, wherein the cleaning agent comprises hydrogen fluoride.
